(19) United States
(12) Patent Application Publication
(10) Pub. No.: US 2026/0096052 A1
(43) Pub. Date: Apr. 2, 2026

(54) OUTDOOR ENCLOSURE WITH ELECTRONIC EQUIPMENT AND LI-ION BATTERIES THAT UTILIZES DIRECT AIR COOLING TO CONTROL INTERNAL TEMPERATURE AND HUMIDITY

(71) Applicant: Vertiv Corporation, Westerville, OH (US)

(72) Inventors: Jin Harrison Elkins, Westerville, OH (US); Jerome Andrew Maloney, Westerville, OH (US); Matthew Allen Podemski, Westerville, OH (US); Paul Gerard Misar, Westerville, OH (US)

(21) Appl. No.: 19/342,172

(22) Filed: Sep. 26, 2025

Related U.S. Application Data
(60) Provisional application No. 63/701,045, filed on Sep. 30, 2024.

(51) Int. Cl. H05K 7/20; H01M 10/613; H01M 10/627; H01M 10/63; H01M 10/6563; H01M 50/251

(52) U.S. Cl. CPC H05K 7/20145; H01M 10/613; H01M 10/627; H01M 10/63; H01M 10/6563; H01M 50/251; H05K 7/20209; H01M 2220/10

(57) ABSTRACT

A telecommunications cabinet can include a base cabinet structure, a front door, an air intake assembly, an exhaust damper, a series of batteries, a telecommunications unit, and a battery dehumidification system, with the front door, the air intake assembly, the exhaust damper, the batteries, the telecommunications unit, and the battery dehumidification system all carried on or in the base cabinet structure, as the case may be. The battery dehumidification system can include at least one fan and at least one of a thermostat and at least one environmental (temperature and/or humidity) sensor. The thermostat and/or one or more environmental sensors can generate a corresponding operational signal, the one or more corresponding operational signal configured to selectively control the operation of the one or more fans to selectively force at least a portion of the waste heat from the telecommunications unit towards the battery.

### CROSS REFERENCE TO RELATED PATENT APPLICATIONS

This application claims the benefit of U.S. Provisional Patent Application No. 63/701,045, filed Sep. 30, 2024, and entitled “OUTDOOR ENCLOSURE WITH ELECTRONIC EQUIPMENT AND LI-ION BATTERIES THAT UTILIZES DIRECT AIR COOLING TO CONTROL INTERNAL TEMPERATURE AND HUMIDITY,” which is incorporated herein by reference in its entirety.

### BACKGROUND

An outside plant (OSP) cabinet (often used for telecommunications purposes) placed in an outside environment can experience humidity and temperature fluctuations. The temperature fluctuations can adversely affect lithium-ion (Li-ion) batteries, particularly warmer temperature spikes. Li-ion batteries have a defined upper safe-operating temperature of about 60° C. or less to avoid catastrophic failure. Thus, Li-ion batteries have heretofore not been employed in non-air-conditioned situations, like OSP cabinets. Further, under certain conditions warm humid air trapped within the battery compartment can condense as the ambient temperatures fall. This condensation can lead to corrosion issues in the cabinet. In addition, batteries tend to operate best within a temperature range and can often require heaters to maintain optimal temperatures in low ambient conditions.

### BRIEF DESCRIPTION OF THE DRAWINGS

The Detailed Description is described with reference to the accompanying figures.

FIGS. 1A-1E are a series of views of an electronics cabinet (e.g., an outside plant (OSP) cabinet), in accordance with an example embodiment of the present disclosure.

FIG. 2 is a side, graphic illustration of an electronics cabinet (e.g., an outside plant (OSP) cabinet), in accordance with an example embodiment of the present disclosure, without a battery dehumidification system in place.

FIG. 3 is a side, graphic illustration of an outdoor plant cabinet, as shown in FIG. 2, with a battery dehumidification system in place.

FIG. 4 is a front, isometric view of an OSP cabinet implementing a battery dehumidification system, without the front door shown, in accordance with an embodiment of the present disclosure.

FIG. 5 is a side, front, isometric view of an OSP cabinet, as shown in FIG. 4, again without the front door shown.

FIG. 6 is a side, rear, isometric view of the OSP cabinet, as shown in FIG. 4, with the upper back panel in place.

FIG. 7 is a side, rear, isometric view of the OSP cabinet, as shown in FIG. 4, without the upper back panel in place.

FIG. 8 is a top, side, isometric view of the upper portion of the OSP cabinet shown in FIG. 4, again without the upper back panel in place.

### DETAILED DESCRIPTION

Aspects of the disclosure are described more fully hereinafter with reference to the accompanying drawings, which form a part hereof, and which show, by way of illustration, example features. The features can, however, be embodied in many different forms and should not be construed as limited to the combinations set forth herein; rather, these combinations are provided so that this disclosure will be thorough and complete, and will fully convey the scope. The following detailed description is, therefore, not to be taken in a limiting sense. In one aspect, features of the disclosure are executed in a computer system.

### INTRODUCTION

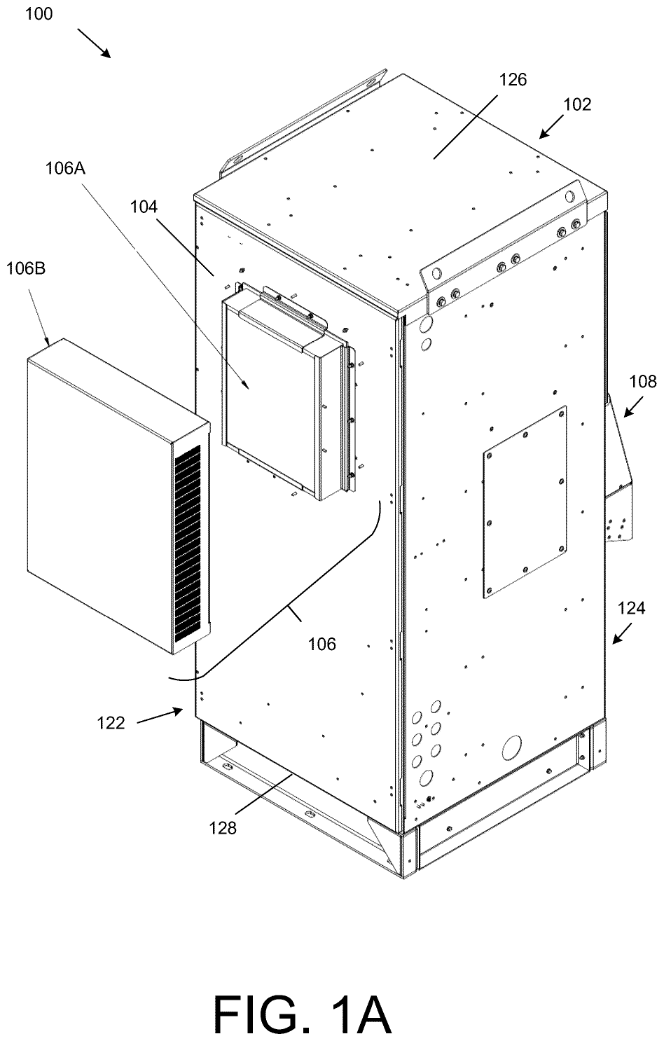

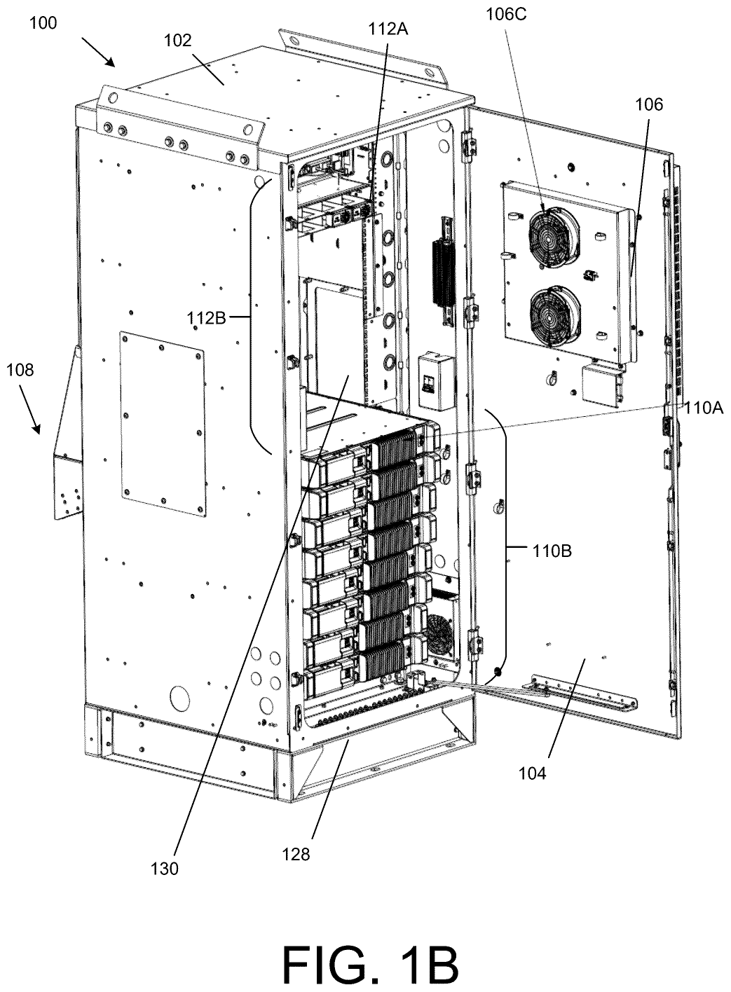

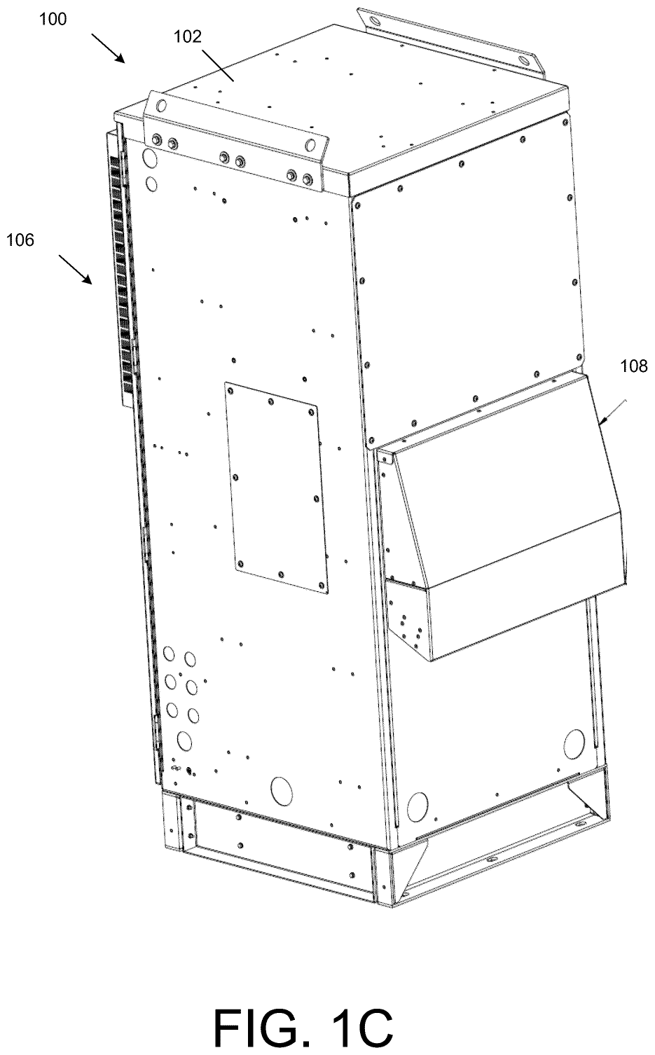

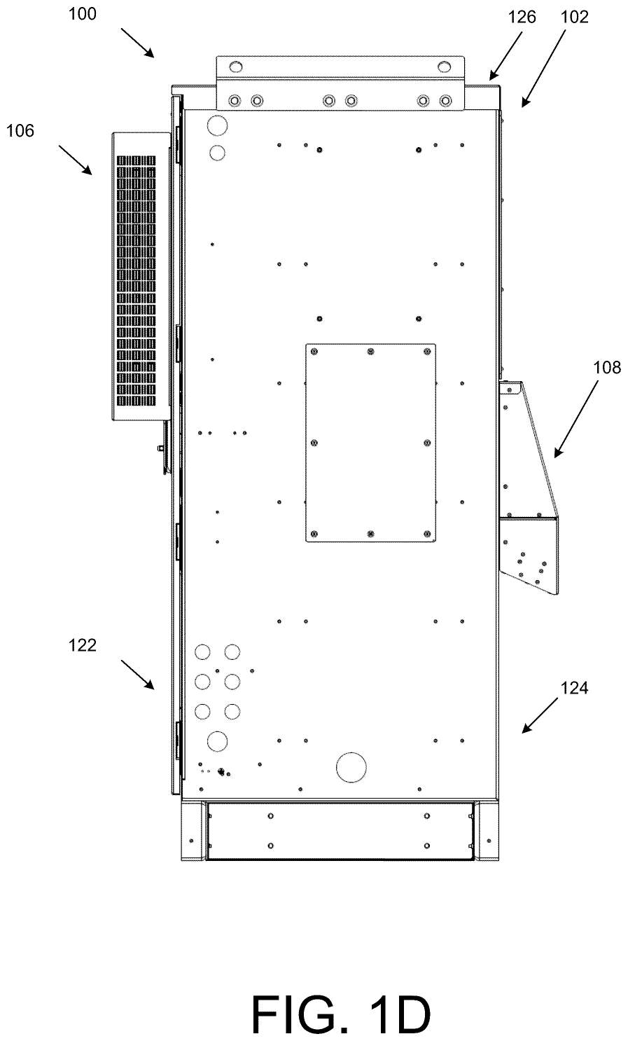

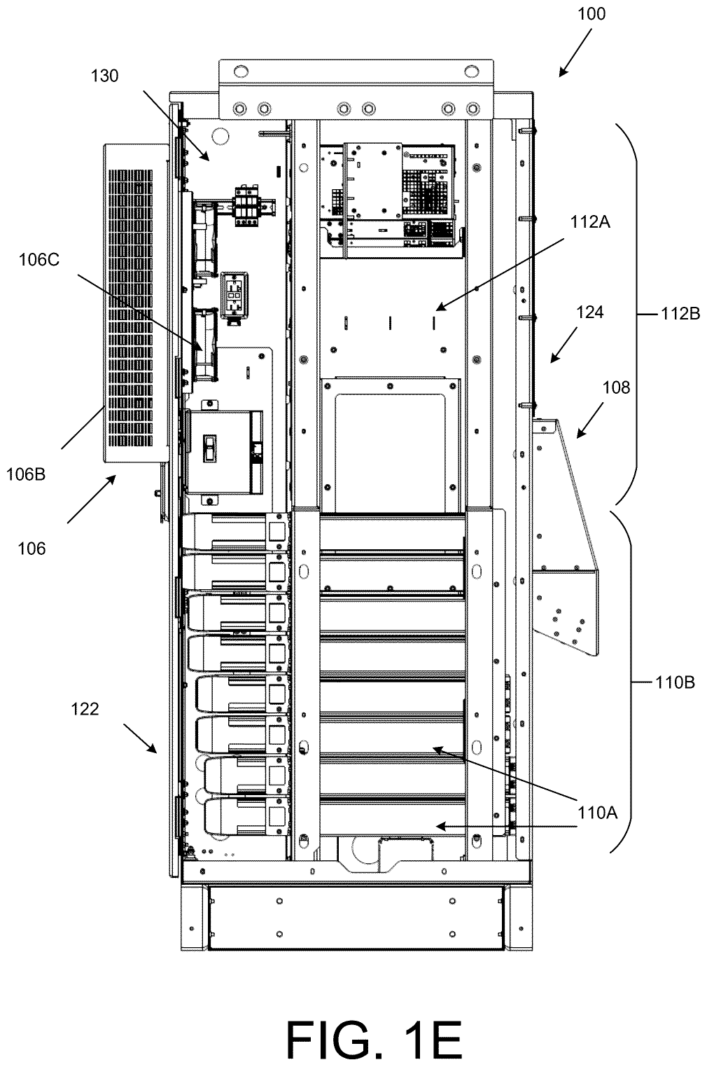

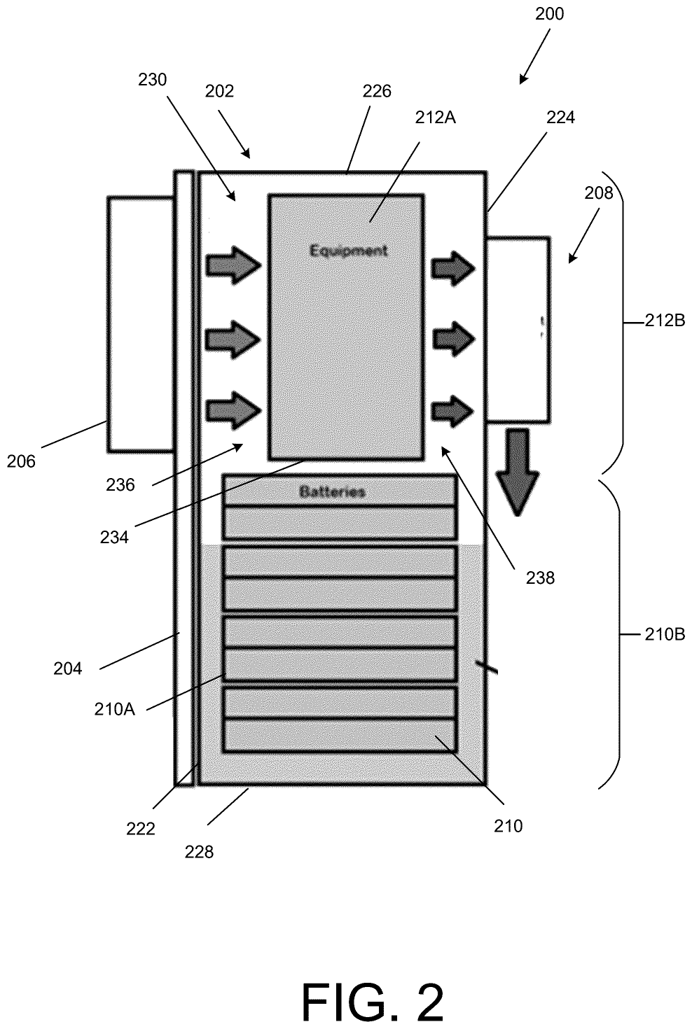

An electronics cabinet can typically house heat-generating electronics (e.g., telecommunications equipment) in an upper portion of the cabinet and a series of lithium-ion (Li-ion) batteries in the lower portion thereof, as illustrated in FIGS. 1A-1E; and FIG. 2, for example. In an embodiment, the electronics cabinet can be an outdoor electronics cabinet, and such cabinets are often referred to as an OSP cabinet. An electronics cabinet can include a front door and a cabinet rear. The front door can have a filter/vent system mounted thereto, with the filter/vent system configured to cool the telecommunications (telecom) equipment and batteries located in the electronics cabinet. The cabinet rear can have an exhaust damper mounted thereto, where the exhaust damper can be configured to allow warm and/or hot air to escape the electronics cabinet and to prevent the back flow of contaminants into the cabinet. In this electronics cabinet, the batteries can be positioned below the heat-generating electronics equipment. (It is to be understood that, while the electronics equipment may generate more heat during operation than the batteries, the batteries can also generate heat due to the resistance associated therewith, heat which must be accommodated for, along with that associated with that generated by the electronics equipment.)

The filter vent system and the exhaust damper together can primarily facilitate the expulsion of hot air (e.g., generated by the electronics equipment and/or the batteries) from the cabinet. The airflow and related cooling promoted by the presence of the filter vent system and the exhaust damper obviate the need for an air conditioning system to keep the Li-ion batteries from exceeding their maximum safe operating temperature. The adequate cooling by the present airflow system alone can permit the use of Li-ion batteries in outdoor electronics cabinets where the use of air conditioning is not necessarily feasible or is at least cost prohibitive.

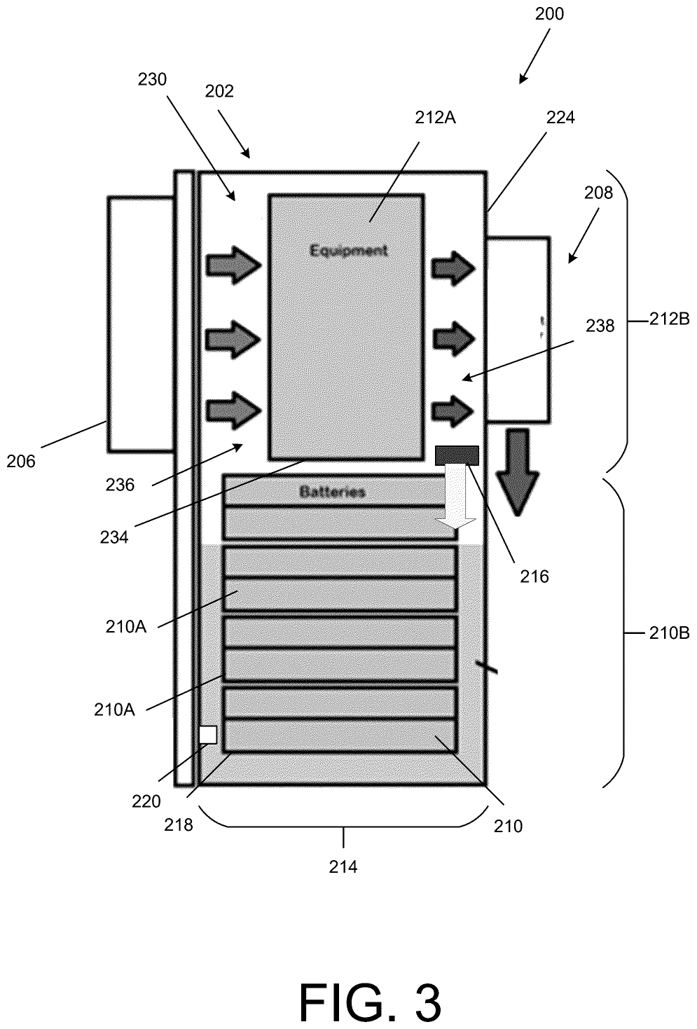

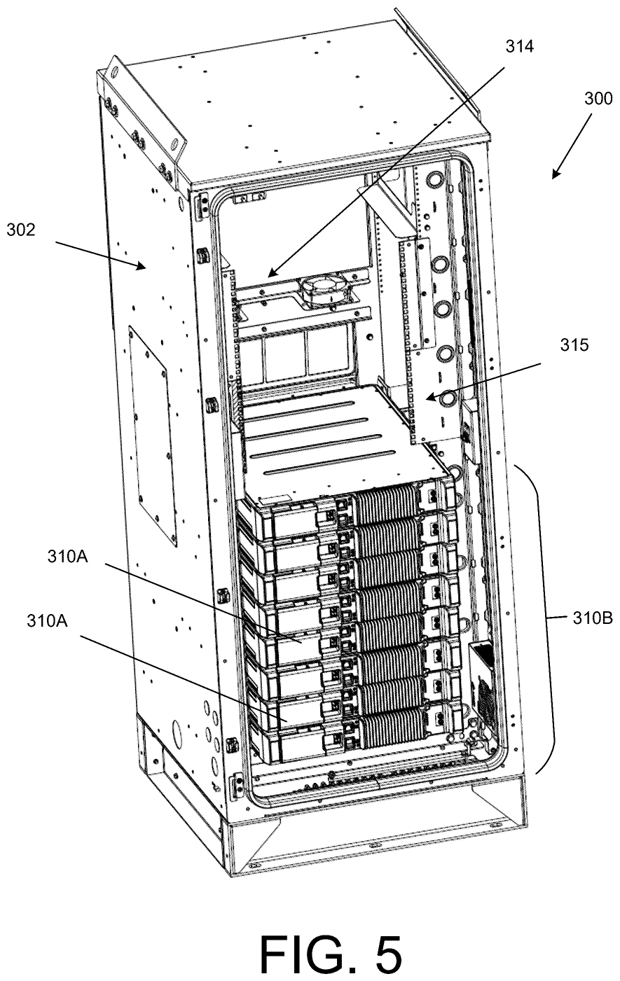

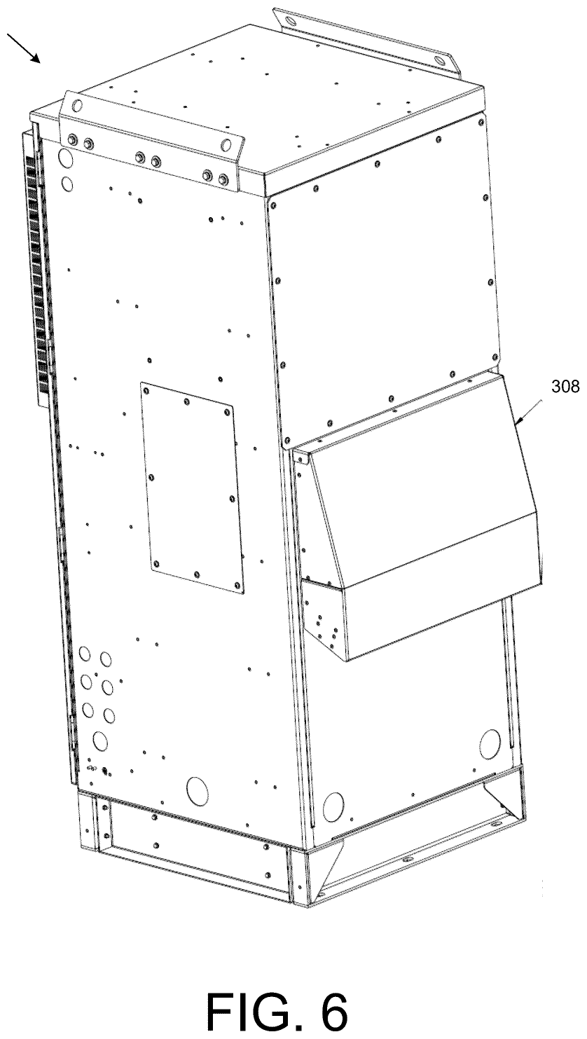

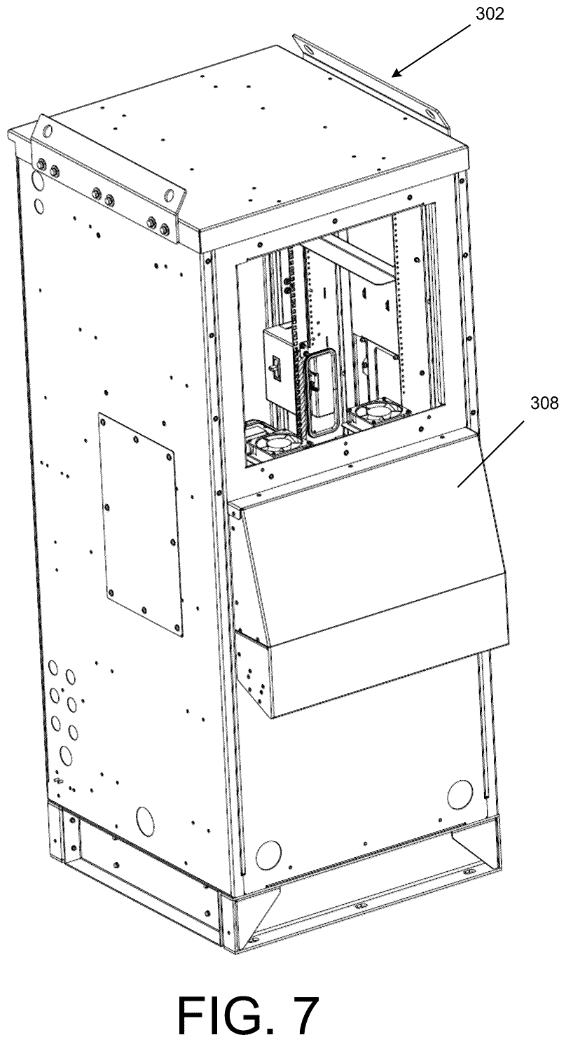

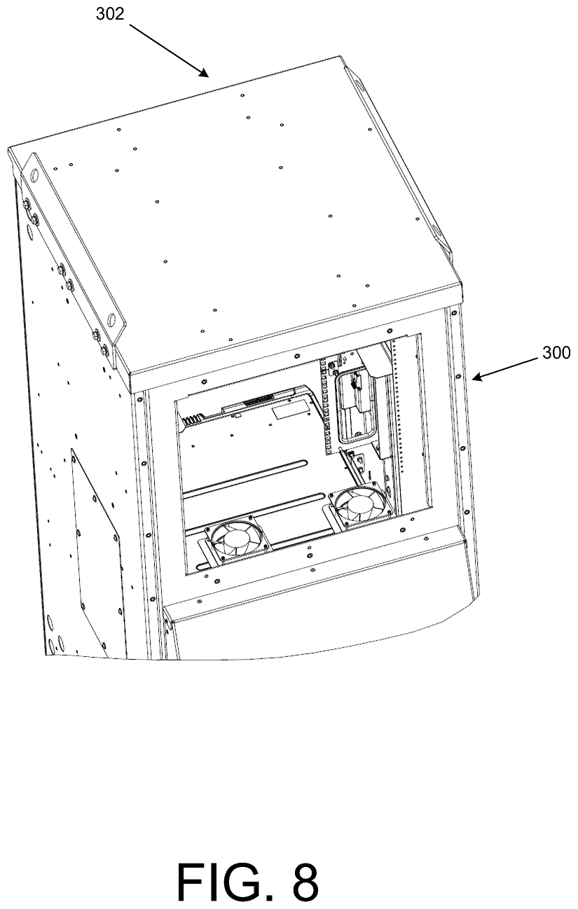

Air can stagnate within the lower portion of the electronics cabinet. Testing has shown that during temperature and humidity cycling, the relative humidity in the lower part of the cabinet can rise. Further, if there is a sharp downturn in temperature while the lower chamber humidity is high, there can be condensation. The present cabinet environment regulating (CER) system, such as graphically illustrated in FIG. 3-8, for use with an electronics cabinet, attempts to address both the humidity and part of the temperature fluctuation associated with electronics cabinets. The CER system can selectively use waste heat generated by the telecommunications equipment within an electronics cabinet to lower a humidity level to a level needed to avoid condensation and/or to avoid poor battery performance; or to raise the temperature of the batteries when the ambient temperature drops and may otherwise make the batteries too cold to perform optimally. As graphically illustrated in FIG. 2, that waste heat has heretofore typically simply been vented to an exhaust damper and, ultimately, to the outside (e.g., ambient) environment.

The present CER system can include one or more fans to redirect waste heat toward the series of batteries housed in the electronics cabinet; one or more temperature sensors proximate the batteries; one or more humidity sensors proximate the batteries; and a system controller configured to regulate operation of the one or more fans based upon the sensed temperature and/or humidity proximate the batteries. In an embodiment, the system controller can include a thermostat configured to control when the one or more fans redirect waste heat from the equipment to supply heat to the batteries (e.g., to drop the relative humidity proximate the batteries and/or to raise the temperature proximate thereto).

At lower ambient temperatures, the cooler, fresh air can be brought in via a cabinet vent, not to mention the cooling of the entire cabinet from exposure thereof to cooler ambient temperatures. Thus, the cooling of the cabinet by either mechanism can likewise drop the temperature of the batteries to an unacceptable level. Likewise, the drop in temperature can promote condensation within the cabinet as temperatures drop below a set point (e.g., the dew point). Under such circumstances, the system controller, based on temperature and/or relative humidity readings proximate the batteries, can be configured to initiate fan operation to drive/draw waste heat toward the batteries until the temperature, proximate the batteries, is appropriately raised (e.g., to avoid condensation by lowering the relative humidity and/or to bring the battery temperature into an optimal operational range). In an embodiment, the system controller can be configured to cause the one or more fans to draw in a sufficient amount of waste heat to keep the temperature proximate to the batteries above the dew point.

Batteries are temperature-sensitive and best perform in a specific temperature range. If the waste heat from the equipment is allowed to constantly flood the battery housing to lower the humidity, the batteries can overheat in high ambient conditions. Waste heat may then only be optimally applied when the battery temperatures drop to levels which can cause condensation or poor battery performance; or when the humidity levels are so high as to promote air stagnation and/or condensation proximate the batteries. This system can include a thermostat and, potentially, one or more environmental (e.g., humidity and/or temperature) sensors to control when the fans supply heat to the batteries.

Fresh air can be brought from the outside as temperatures drop. The lower temperature air can have a lower specific humidity and can lower the relative humidity in the battery chamber, reducing the opportunity for condensation. The problem with this option is that at lower ambient temperatures, the batteries can get too cold. An additional option is to use heaters in the battery compartment upon lowering the humidity with that fresh air intake. These additional heaters can, though, increase energy usage of the cabinet and add extra cost. In an embodiment of the present disclosure, instead of using such additional heaters, upon approaching the bottom of the optimal temperature range of the batteries, the one or more fans can be activated to draw warm waste air from the electronics equipment to a zone proximate the batteries. This active draw of warm air can keep the batteries in an optimal temperature range and/or helping avoid the formation of condensate (e.g., water in its liquid form) that may have a deleterious effect on the batteries (e.g., shorting; corrosion; etc.).

In an embodiment, the telecommunications cabinet can include a base cabinet structure, a front door, an air intake assembly, an exhaust damper, a series of batteries, a telecommunications unit, and a battery dehumidification system, with the front door, the air intake assembly, the exhaust damper, the batteries, the telecommunications unit, and the battery dehumidification system all carried on or in the base cabinet structure, as the case may be. The battery dehumidification system can include at least one fan and at least one of a thermostat and at least one environmental (temperature and/or humidity) sensor. The thermostat and/or one or more environmental sensors can generate a corresponding operational signal, the one or more corresponding operational signal configured to selectively control the operation of the one or more fans to selectively force at least a portion of the waste heat from the telecommunications unit towards the battery.

### Description of Example Embodiments

FIGS. 1A-1E illustrate an electronics cabinet 100, in accordance with an example embodiment of the present disclosure. In some embodiments, the electronics cabinet 100 can be an outdoor electronics cabinet and can be referred to as an OSP cabinet. In an embodiment, the electronics cabinet 100 can be a telecommunications (e.g., telecom) cabinet. The electronics cabinet 100 can generally include a base cabinet structure (e.g., made up of top, bottom, and side walls not individually identified) 102, a front door 104, an air intake assembly 106, an exhaust damper 108, a series of batteries 110A, and a telecommunications unit 112A (e.g., telecom equipment including various electronics needed for the operation thereof and/or the control of the components otherwise housed in the electronics cabinet 100). The telecommunications unit 112A resides in an upper region of the cabinet interior 130, further defining an equipment housing 112B.

In an embodiment, the base cabinet structure 102 of the electronics cabinet 100 can define a cabinet front 122, a cabinet back 124, a cabinet top 126, and a cabinet floor 128, with the base cabinet structure 102 defining a cabinet interior 130 bounded thereby. The series of batteries 110A resides in a lower region of the cabinet interior 130, further defining a battery housing 110B. A front door 104 can be movably mounted (e.g., via hinge (not shown)) to the cabinet front 122 to facilitate access to the cabinet interior 130. The front door 104 can further carry the air intake assembly 106, with the air intake assembly 106 configured to facilitate the intake of filtered ambient air into the cabinet interior 130 and to facilitate the movement of that filtered ambient air toward and through the telecommunications unit 112A within the equipment housing 112B and/or around the series of batteries 110A within the battery housing 110B. The resultant airflow from the air intake assembly 106 can thereby help to cool the telecommunications unit 112A and/or the series of batteries 110A.

As likely best seen in FIGS. 1A, 1B, and ID, an air intake assembly 106 can include, for example, an intake filter 106A; an intake filter shroud 106B; and one or more intake fans 106C (of which two are illustrated). The air intake filter 106A and the air intake filter shroud 106B can be carried (e.g., operatively mounted) to an outside (e.g., ambient-facing side) of the front door 104, and the one or more intake fans 106C can be mounted on an inside (e.g., cabinet interior-facing side) of the front door 104, with the front door 104 configured with a port therethrough (not labeled) to facilitate air flow from the outside (ambient) between the air intake filter 106A and the one or more intake fans 106C. The intake filter 106A, the intake filter shroud 106B, and the one or more intake fans 106C, along with the front door 104, can together help define an air intake flow path from the ambient to the cabinet interior 130, including the equipment housing 112B and the battery housing 110B. The air intake filter shroud 106B can be configured to substantially cover and protect the intake filter 106A, while still defining one or more air flow paths (not labeled) to the intake filter 106A. In an embodiment, the intake filter 106A can be removably mounted (relative the front door 104) to facilitate the replacement and/or cleaning thereof.

As likely best seen from FIG. 1E, the exhaust damper 108 can exhaust and/or vent warm air from the electronics cabinet 100. The exhaust damper 108 can be mounted or otherwise carried on the cabinet back 124, with the cabinet back 124 configured to permit air flow therethrough (e.g., via a port therethrough) proximate the exhaust damper 108 for venting purposes. In an embodiment, the exhaust damper 108 can be relatively centrally located relative to the cabinet back 124 to exhaust warm air from both a series of batteries 110A and the telecommunications unit 112A. In an embodiment, the exhaust damper 108 can be downwardly directed to minimize the possibility of precipitation (e.g., rain and/or snow) and/or dust from entering therethrough into the electronics cabinet 100.

FIGS. 2-3 illustrate an electronics cabinet 200 (also called, in some embodiments, a telecommunications (e.g., telecom) cabinet), in accordance with an example embodiment of the present disclosure. The electronics cabinet 200 can be an outdoor electronics cabinet, and such cabinets are commonly referred to as an outside plant (OSP) cabinet. It is to be understood that similarly numbered parts (e.g., electronics cabinet 100, 200) can be expected to have similar construction and operating characteristics unless otherwise expressly stated. The electronics cabinet 200 can generally include a base cabinet structure (e.g., made up of top, bottom, and side walls not individually identified) 202, a front door 204, an air intake assembly 206 (e.g., including a fan and filter, each not individually identified), an exhaust damper 208, a series of batteries 210A, a telecommunications unit 212A (e.g., telecom equipment including various electronics needed for the operation thereof and/or the control of the components otherwise housed in the electronics cabinet 200), and a battery dehumidification system 214. The battery dehumidification system 214 can include one or more fans 216 and a thermostat 218 and can further include one or more environmental (e.g., temperature and/or humidity) sensors 220.

In an embodiment, the base cabinet structure 202 of the electronics cabinet 200 can define a cabinet front 222, a cabinet back 224, a cabinet top 226, and a cabinet floor 228, with the base cabinet structure 202 defining a cabinet interior 230 bounded thereby. A front door 204 can be movably mounted (e.g., via hinge (not shown)) to the cabinet front 222 to facilitate access to the cabinet interior 230. The front door 204 can further carry the air intake assembly 206, with the air intake assembly 206 configured to facilitate the intake of filtered ambient air into the cabinet interior 230 and to facilitate the movement of that filtered ambient air toward and through the telecommunications unit 212A.

The series of batteries 210A, a telecommunications unit 212A, and the battery dehumidification system 214 can be housed within the base cabinet structure 202, with the telecommunications unit 212A residing within an upper region of the cabinet interior 230, further defining an equipment housing 212B, and the series of batteries 210A residing within a lower region of the cabinet interior 230, further defining a battery housing 210B. Within the battery housing 210B, the series of batteries 210A (e.g., battery stack) can be carried proximal to the cabinet floor 228, with the battery stack extending upwardly from the cabinet floor 228. In an embodiment, the batteries 210A can be lithium-ion (Li-ion) batteries. In an embodiment, Li-ion batteries can have specific temperature and/or humidity windows in which they can safely operate, and the battery dehumidification system 214 can be configured to help operate the present electronics cabinet 200 within such windows. The telecommunications unit 212A can be carried above (e.g., atop) the series of batteries 210A, inside of the equipment housing 212B and outside of the battery housing 210B.

It is to be understood that the series of batteries 210A, the telecommunications unit 212A, and the battery dehumidification system 214 can ultimately be carried by a rack system (not shown here, for case of illustration). The one or more fans 216 can be mounted proximate the juncture of the telecommunications unit 212A and the series of batteries 210A at a periphery between the equipment housing 212B and the battery housing 210B (by way of example, as illustrated by the boundary between unshaded and shaded regions of FIG. 2), with an intake side of the one or more fans facing the equipment housing 212B and an exhaust side of the one or more fans 216 facing the battery housing 210B, and, more specifically, the one or more fans 216 can be mounted proximal a unit base 234 of the telecommunications unit 212A. Further, the one or more fans 216 can be positioned between the telecommunications unit 212A and the cabinet back 224. It is to be understood that the airflow migrating through the telecommunications unit 212A and flowing out of the equipment housing 212B can be warmed in the process of otherwise cooling the telecommunications unit 212A. Thus, the equipment housing 212B, based on the airflow direction therethrough, can be considered to define a cool entry side 236 and a warm exit side 238 when in operation, with the cool entry side 236 facing the cabinet front 222 and the air intake assembly 206 and with the warm exit side 238 facing the cabinet back 224 and the exhaust damper 208 carried by the cabinet back 224.

The thermostat 218 and/or any environmental sensors 220 can be positioned proximate the batteries 210A and can be operatively coupled (e.g., wirelessly or via a wired connection), whether directly and/or indirectly (e.g., via a controller or processor (not shown)), with the one or more fans 216. The thermostat 218 and/or any environmental sensors 220 can be configured to communicate, via such coupling, with the one or more fans 216 to help drive selective operation thereof (e.g., selective operation of the one or more fans 216 being conditioned on signals derived from the thermostat 218 and/or any environmental sensors 220). In an embodiment, the thermostat 218 and/or any environmental sensors 220 specifically can be positioned near the cabinet floor 228 (e.g., proximate the base/bottom of the battery stack) within the battery housing 210B. In an embodiment, the thermostat 218 and/or any environmental sensors 220 can specifically be positioned near the cabinet floor 228 and proximate the cool entry side 236 and/or the cabinet front 222 (e.g., near the front, bottom corner of the battery stack) within the battery housing 210B. The front, bottom corner of the battery stack may most condensation-prone, as that can define the coolest portion of the battery stack (e.g., proximal the cool entry side 236 via the air intake assembly 206, while being most distal to the warm exit side 238 of the equipment housing 212B) and thus the coolest region within the battery housing 210B.

FIG. 2 illustrates the electronics cabinet 200 without the added battery dehumidification system 214. During operation under that scenario, cooler ambient air can be drawn through the air intake assembly 206 (e.g., driven by the fan and flowing through the filter thereof) into the cabinet interior 230 and driven into the telecommunications unit 212A (e.g., telecom equipment). The air, upon flowing through the equipment housing 212B and cooling the telecom equipment, is warmed in the process, leaving the warm exit side 238 of the equipment housing 212B and being vented to the exhaust damper 208 carried by the cabinet back 224. As discussed with respect to FIGS. 1A-1E, the cooling provided by the interaction of the air intake assembly 206 and the exhaust damper 208 can be a primary system benefit, separate and apart from those benefits provided by the battery dehumidification system 214. Under the scenario of FIGS. 1A-1E, though, as the ambient air temperatures drop, there is an increased chance of condensation within the battery housing 210B proximate the batteries 210A (e.g., the battery housing discussed in FIGS. 1A-1E) as the battery chamber temperatures drop. That is, as ambient temperatures drop, the entire electronics cabinet 200 can experience cooling (e.g., via conduction), plus the intake of the cooler ambient air can directly cool the cabinet interior 230.

FIG. 3 illustrates the electronics cabinet 200 with the benefit of the battery dehumidification system 214 of the present disclosure. Like with the scenario of FIG. 2, the air can be warmed upon flowing through the equipment housing 212B and across the telecommunications unit 212A (e.g., telecom equipment). In a situation where the temperature and/or humidity levels proximate the batteries 210A (as signaled by the thermostat 218 and/or any environmental sensors 220 of the battery dehumidification system 214) dictate, the one or more fans 216 can be configured to selectively operate to supply warm dry air from the equipment housing 212B to the battery housing 210B to offset cooling of the batteries 210A and otherwise prevent condensation. In an embodiment, the thermostat 218 can be configured to selectively activate the one or more fans 216 as the temperatures fall in the battery housing 210B and, likewise, selectively terminate operation thereof as temperatures rise (e.g., above the dew point). In an embodiment, one or more environmental sensors (temperature, humidity, and/or combined temperature and humidity) can be configured to communicate (e.g., via a controller or processor) with the one or more fans 216 to selectively initiate/stop (as needed) the operation of the one or more fans 216. During active operation of the one or more fans 216, the battery housing 210B can be dehumidified by the equipment waste heat offsetting cooling of the battery housing 210B. That is, during active operation of the one or more fans 216, rather than all the waste heat exiting the equipment housing 212B from the exhaust damper 208, a portion of the waste heat can be pushed toward the batteries 210A by the one or more fans 216, using that waste heat to offset cooling and dehumidify the battery housing 210B. In an embodiment, the battery dehumidification system 214 can be considered as selectively using the waste heat from the telecom equipment to actively condition the battery housing 210B, as needed, keeping the batteries 210A in an optimal operating range and/or deterring the formation of condensation proximate thereto.

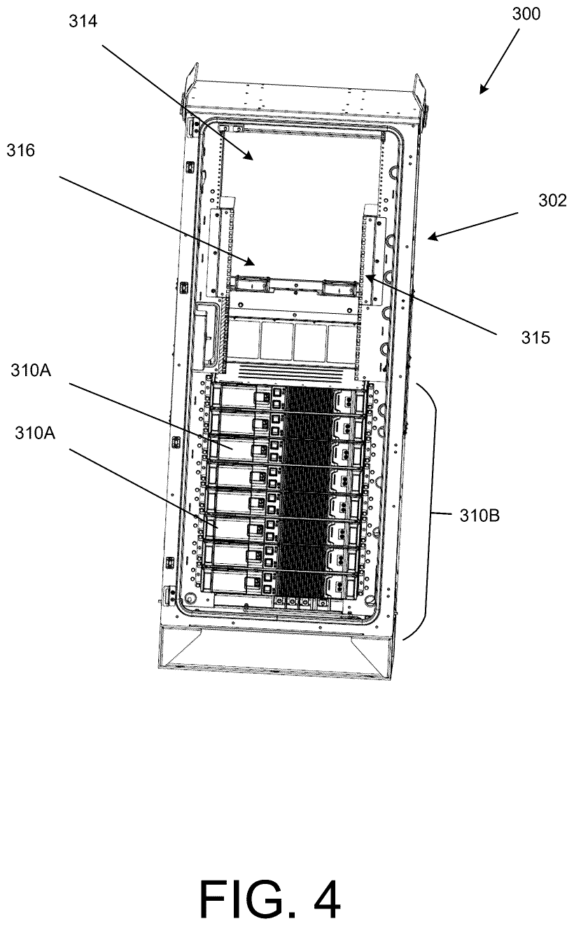

FIGS. 4-8 illustrate an electronics cabinet 300, in accordance with a second embodiment of the present disclosure. The electronics cabinet 300 can be expected to function in a similar manner as the electronics cabinet 200. Essentially, the electronics cabinet 300 is more granularly illustrated than the electronics cabinet 200. Thus, similarly numbered parts between the two embodiments can be expected to have a similar construction and functionality. The electronics cabinet 300 can generally include a base cabinet structure (e.g., made up of top, bottom, and side walls not individually identified) 302, an exhaust damper 308, a series of batteries 310A within a battery housing 310B, and a battery dehumidification system 314, along with a rack structure 315. The battery dehumidification system 314 can include one or more fans 316 and a thermostat and can further include one or more environmental (e.g., temperature and/or humidity) sensors (the thermostat and/or environment sensors not shown in the second embodiment). The rack structure 315 can be mounted within the base cabinet structure 302 and can be configured to carry the series of batteries 310A and the battery dehumidification system 314. For ease of illustration, the front door, the air intake assembly (e.g., including a fan and filter), and telecom equipment are not shown in this set of views, but it is to be understood that these can also be in place within an operable version of the electronics cabinet 300. It is to be further understood that the telecom equipment can also be carried by the rack structure 315 when in place.

The electronics cabinet 100, 200, 300 can further include at least one processor for controlling the operation of the various components of the electronics cabinet 100, 200, 300. The at least one processor may, for example, be part of the telecommunications unit 112A, 212A and can be implemented as any suitable processor(s), such as at least one general purpose processor, at least one central processing unit (CPU), at least one image processor, at least one graphics processing unit (GPU), at least one field-programmable gate array (FPGA), and/or at least one special purpose processor configured to execute instructions for performing (e.g., collectively performing if more than one processor) any or all of the operations disclosed throughout. Further, any of the embodiments can incorporate one or more environmental sensors, as appropriate, to aid in the temperature and/or humidity control of a given electronics cabinet 100, 200, 300 (even if a battery dehumidification system 214, 314 is not present).

In one embodiment, several portions of the subject matter described herein can be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link, etc.).

In a general sense, those skilled in the art will recognize that the various aspects described herein which can be implemented, individually and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application-specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein can be implemented in an analog or digital fashion or some combination thereof.

Those having skill in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system can be implemented utilizing any suitable commercially available components, such as those typically found in data computing/communication and/or network computing/communication systems.

As used throughout and as would be appreciated by those skilled in the art, “at least one non-transitory computer-readable medium” or “memory” can refer to as at least one non-transitory computer-readable medium (e.g., at least one computer-readable medium implemented as hardware); at least one non-transitory processor-readable medium, at least one memory (e.g., at least one nonvolatile memory, at least one volatile memory, or a combination thereof); e.g., at least one random-access memory, at least one flash memory, at least one read-only memory (ROM) (e.g., at least one electrically erasable programmable read-only memory (EEPROM)), at least one on-processor memory (e.g., at least one on-processor cache, at least one on-processor buffer, at least one on-processor flash memory, at least one on-processor EEPROM, or a combination thereof), or a combination thereof), at least one storage device (e.g., at least one hard-disk drive, at least one tape drive, at least one solid-state drive, at least one flash drive, at least one readable and/or writable disk of at least one optical drive configured to read from and/or write to the at least one readable and/or writable disk, or a combination thereof), or a combination thereof.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Those having skill in the art will recognize that the state of the art has progressed to the point where there is little distinction left between hardware and software implementations of aspects of systems; the use of hardware or software is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be implemented (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein can be implemented, none of which is inherently superior to the other in that any vehicle to be utilized is a choice dependent upon the context in which the vehicle will be deployed and the specific concerns (e.g., speed, flexibility, or predictability) of the implementer, any of which may vary.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A cabinet comprising:
a cabinet structure;
a battery housing configured to contain a plurality of batteries within the cabinet structure;
an equipment housing configured to contain a telecommunications unit within the cabinet structure; and
a fan carried within the cabinet structure, wherein an intake side of the fan faces the equipment housing, and an exhaust side of the fan faces the battery housing.

2. The cabinet of claim 1, further comprising:
a door mounted on the cabinet structure;
an air intake assembly carried by the door; and
an exhaust damper carried by the cabinet structure on a side of the cabinet structure opposite the door,
wherein the air intake assembly and exhaust damper are configured to draw ambient air through the cabinet.

3. The cabinet of claim 2, wherein the cabinet is configured for placement in a location outdoors.

4. The cabinet of claim 1, wherein the equipment housing is configured to carry the telecommunications unit above the battery housing within the cabinet structure.

5. The cabinet of claim 1, wherein the cabinet further comprises a thermostat, wherein the thermostat is configured to control the fan, based at least in part on a sensed temperature within the battery housing, to direct heat from the equipment housing toward the battery housing.

6. The cabinet of claim 5, wherein the cabinet comprises a plurality of fans each having an intake side facing the equipment housing and an exhaust side facing the battery housing.

7. The cabinet of claim 1, wherein the cabinet further comprises a humidity sensor, wherein the humidity sensor is configured to control the fan, based at least in part on a sensed humidity level within the battery housing, to direct heat from the equipment housing toward the battery housing.

8. The cabinet of claim 7, wherein the cabinet comprises a plurality of fans each having an intake side facing the equipment housing and an exhaust side facing the battery housing.

9. A cabinet comprising:
a cabinet structure;
a battery housing configured to contain a plurality of batteries within the cabinet structure;
an equipment housing configured to contain a telecommunications unit within the cabinet structure; and
a fan carried within the cabinet structure, wherein an intake side of the fan faces the equipment housing, and an exhaust side of the fan faces the battery housing.

10. The cabinet of claim 9, further comprising:
a door mounted on the cabinet structure;
an air intake assembly carried by the door; and
an exhaust damper carried by the cabinet structure on a side of the cabinet structure opposite the door,
wherein the air intake assembly and exhaust damper are configured to draw ambient air through the cabinet.

11. The cabinet of claim 10, wherein the cabinet is configured for placement in a location outdoors.

12. The cabinet of claim 9, wherein the equipment housing is configured to carry the telecommunications unit above the battery housing within the cabinet structure.

13. The cabinet of claim 9, wherein the cabinet further comprises at least one environmental sensor, the at least one environmental sensor configured to generate a corresponding operational signal based on at least one of (i) a temperature within the battery housing or (ii) a humidity level within the battery housing, the corresponding operational signal configured to selectively control operation of the fan to direct heat from the equipment housing toward the battery housing.

14. The cabinet of claim 13, wherein the cabinet comprises a plurality of fans each having an intake side facing the equipment housing and an exhaust side facing the battery housing.

15. The cabinet of claim 13, wherein the at least one environmental sensor comprises a thermostat, wherein the thermostat is configured to selectively control the fan via the corresponding operational signal, based at least in part on a sensed temperature within the battery housing, to direct heat from the equipment housing toward the battery housing.

16. The cabinet of claim 15, wherein the cabinet comprises a plurality of fans each having an intake side facing the equipment housing and an exhaust side facing the battery housing.

17. The cabinet of claim 13, wherein the at least one environmental sensor comprises a humidity sensor, wherein the humidity sensor is configured to control the via the corresponding operational signal, based at least in part on a sensed humidity level within the battery housing, to direct heat from the equipment housing toward the battery housing.

18. The cabinet of claim 17, wherein the cabinet comprises a plurality of fans each having an intake side facing the equipment housing and an exhaust side facing the battery housing.

19. A cabinet configured for placement in a location outdoors, the cabinet comprising:
a cabinet structure;
a door mounted on the cabinet structure;
an air intake assembly carried by the door;
an exhaust damper carried by the cabinet structure on a side of the cabinet structure opposite the door;
a battery housing configured to contain a plurality of batteries carried within the cabinet structure;
an equipment housing configured to contain a telecommunications unit within the cabinet structure; and
a fan carried within the cabinet structure, wherein an intake side of the fan faces the equipment housing, and an exhaust side of the fan faces the battery housing, wherein the air intake assembly and exhaust damper are configured to draw ambient air through the cabinet.

20. The cabinet of claim 19, wherein the cabinet comprises at least one environmental sensor including at least one of (i) a temperature sensor, (ii) a humidity sensor, or (iii) a combination temperature and humidity sensor, the at least one environmental sensor configured to generate a corresponding operational signal based on at least one of (a) a temperature within the battery housing or (b) a humidity level within the battery housing, the corresponding operational signal configured to selectively control operation of one or more of the fan to direct heat from the equipment housing toward the battery housing.
